(19) United States
(12) Patent Application Publication
(10) Pub. No.: US 2026/0048402 A1
(43) Pub. Date: Feb. 19, 2026

(54) PNEUMATIC CONTROL NOZZLE ASSEMBLY, SUBSTRATE PROCESSING DEVICE AND CONTROL METHOD THEREOF

(71) Applicant: GRAND PROCESS TECHNOLOGY CORPORATION, Hsinchu City (TW)

(72) Inventors: Zong-en WU, Hsinchu City (TW); Chun-hao LIN, Hsinchu City (TW)

(21) Appl. No.: 19/054,861

(22) Filed: Feb. 16, 2025

(30) Foreign Application Priority Data
Aug. 13, 2024 (TW) 113130377

(51) Int. Cl. B05B 1/30; H01L 21/67

(52) U.S. Cl. CPC B05B 1/3013; H01L 21/67017

(57) ABSTRACT

A pneumatic control nozzle assembly, a substrate processing device and a control method thereof are provided. The pneumatic control nozzle assembly includes a nozzle body, a closed movable element, and a pneumatic driving part. The nozzle body includes an inlet end, an outlet end, and an internal channel. The closed movable element is movably disposed in the internal channel of the nozzle body. The pneumatic driving part is connected to the nozzle body and the closed movable element, and is configured to drive the closed movable element to perform a linear movement in the internal channel so that the nozzle body changes between an open state and a closed state. When the nozzle body is in the closed state, the closed movable element plugs the outlet end located at an end of the nozzle body.

### CROSS REFERENCE TO RELATED APPLICATIONS

This application claims priority to Taiwan Application Serial No. 113130377, filed Aug. 13, 2024, the disclosure of which is incorporated herein by reference.

### FIELD OF DISCLOSURE

The present application relates to the field of semiconductor equipment, and in particular to a pneumatic control nozzle assembly, a substrate processing device and a control method thereof.

### BACKGROUND TECHNOLOGY

In a cleaning or etching process of a single wafer, when a wet etching or cleaning process is about to end, a pipeline valve related to supply of chemical liquid is usually closed first to stop the supply of the chemical liquid. However, since the chemical liquid itself has weight, this often causes a residual chemical liquid inside a nozzle to drip from an end of the nozzle onto a wafer surface above a wafer spin chuck. This situation may cause chemical liquid contamination on the wafer surface and even cause process problems such as over-etching.

Accordingly, it is necessary to provide a pneumatic control nozzle assembly, a substrate processing device and a control method thereof to solve the above technical problems.

### SUMMARY OF INVENTION

In order to make the above and other purposes, features, and advantages of the present disclosure more comprehensible, preferred embodiments of the present disclosure will be described below in detail together with the accompanying drawings.

In a first aspect, the present application provides a pneumatic control nozzle assembly, including: a nozzle body, a closed movable element, and a pneumatic driving part. The nozzle body includes an inlet end, an outlet end, and an internal channel, and the internal channel connects the inlet end and the outlet end. The closed movable element is movably disposed in the internal channel of the nozzle body. The pneumatic driving part is connected to the nozzle body and the closed movable element, and is configured to drive the closed movable element to perform a linear movement in the internal channel so that the nozzle body changes between an open state and a closed state. When the nozzle body is in the closed state, the closed movable element plugs the outlet end located at an end of the nozzle body.

In some embodiments, when the nozzle body is in the closed state, an end of the closed movable element protrudes out of the outlet end of the nozzle body.

In some embodiments, when the nozzle body is in the closed state, an end of the closed movable element is flush with the outlet end of the nozzle body.

In some embodiments, when the nozzle body is in the open state, an end of the closed movable element is spaced a distance from the outlet end of the nozzle body and a tube wall of the internal channel.

In some embodiments, the linear movement of the closed movable element includes movement toward or away from the outlet end of the nozzle body.

In a second aspect, the present application further provides a substrate processing device, including: a substrate supporting portion, a liquid supply system, and a pneumatic control nozzle assembly. The substrate supporting portion is configured to support a substrate. The liquid supply system is configured to provide a liquid. The pneumatic control nozzle assembly is connected to the liquid supply system and is configured to apply the liquid to the substrate. The pneumatic control nozzle assembly includes: a nozzle body, a closed movable element, and a pneumatic driving part. The nozzle body includes an inlet end, an outlet end, and an internal channel. The internal channel connects the inlet end and the outlet end, and the nozzle body allows the liquid to enter through the inlet end and flow through the internal channel and then be discharged from the outlet end. The closed movable element is movably disposed in the internal channel of the nozzle body. The pneumatic driving part is connected to the nozzle body and the closed movable element, and is configured to drive the closed movable element to perform a linear movement in the internal channel so that the nozzle body changes between an open state and a closed state. When the nozzle body is in the closed state, the closed movable element plugs the outlet end located at an end of the nozzle body.

In some embodiments, when the nozzle body is in the closed state, an end of the closed movable element protrudes out of the outlet end of the nozzle body.

In some embodiments, when the nozzle body is in the closed state, an end of the closed movable element is flush with the outlet end of the nozzle body.

In a third aspect, the present application further provides a control method of a substrate processing device, including: providing a substrate processing device, where the substrate processing device includes a substrate supporting portion, a liquid supply system, and a pneumatic control nozzle assembly connected to the liquid supply system; and the pneumatic control nozzle assembly includes a nozzle body, a closed movable element, and a pneumatic driving part, the nozzle body includes an inlet end, an outlet end, and an internal channel, the closed movable element is movably disposed in the internal channel of the nozzle body, and the pneumatic driving part is connected to the nozzle body and the closed movable element; disposing a substrate on the substrate supporting portion; driving the closed movable element by the pneumatic driving part to move away from the outlet end of the nozzle body, so that the nozzle body is in an open state; starting the liquid supply system to apply a liquid onto the substrate through the pneumatic control nozzle assembly; and driving the closed movable element by the pneumatic driving part to move toward the outlet end of the nozzle body until the closed movable element plugs the outlet end located at an end of the nozzle body, so that the nozzle body is in a closed state.

In some embodiments, before driving the closed movable element by the pneumatic driving part to move toward the outlet end of the nozzle body, the control method further includes: stopping the liquid supply system; and drawing a residual liquid away from the internal channel by a suck back mechanism.

Compared with the prior art, the present application provides the pneumatic control nozzle assembly, the substrate processing device and the control method thereof. When the nozzle body is in the closed state, the closed movable element plugs the outlet end at the end of the nozzle body, so that no space or channel for accommodating residual liquid is left on a side of the closed movable member facing outward. This ensures that no excess liquid drips from the nozzle body in the closed state.

### BRIEF DESCRIPTION OF THE DRAWINGS

FIG. 1 is a schematic diagram of a substrate processing device according to an embodiment of the present application.

FIG. 2 is a schematic diagram showing a nozzle body of a pneumatic control nozzle assembly in an open state according to an embodiment of the present application.

FIG. 3 is a schematic diagram showing a nozzle body of a pneumatic control nozzle assembly in a closed state according to an embodiment of the present application.

FIG. 4 is a partial enlarged view of a nozzle body of a pneumatic control nozzle assembly in a closed state according to another embodiment of the present application.

FIG. 5 is a flowchart of a control method of a substrate processing device according to an embodiment of the present application.

### DETAILED DESCRIPTION

In order to make the above and other purposes, features and advantages of the present application more obvious and easy to understand, preferred embodiments of the present application will be specifically listed below and described in detail with reference to accompanying drawings.

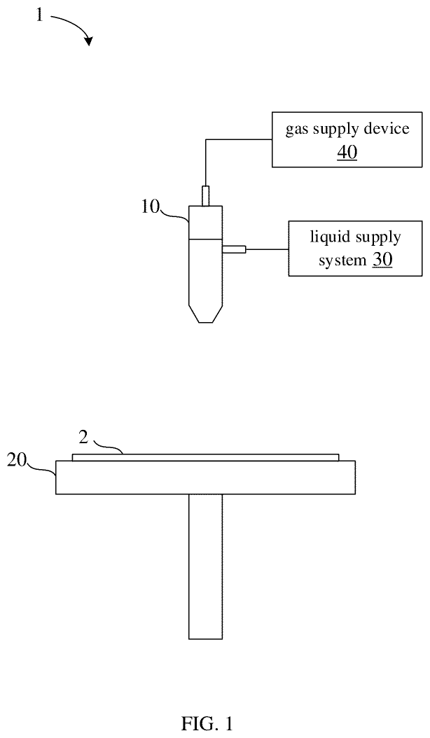

Please refer to FIG. 1, which is a schematic diagram of a substrate processing device according to an embodiment of the present application. The substrate processing device 1 includes a pneumatic control nozzle assembly 10, a substrate supporting portion 20, a liquid supply system 30, and a gas supply device 40. The substrate supporting portion 20 is configured to support the substrate 2 thereon. The substrate supporting portion 20 may be designed to be rotatable about an axis. Moreover, a vacuum suction or clamping can be configured to maintain the stability of the substrate 2. The liquid supply system 30 is configured to provide liquid and is connected to the pneumatic control nozzle assembly 10. The pneumatic control nozzle assembly 10 is configured to apply liquid from the liquid supply system 30 onto a surface of the substrate 2 disposed on the substrate supporting portion 20 to perform operations such as cleaning and etching. Furthermore, the gas supply device 40 is connected to the pneumatic control nozzle assembly 10 for providing gas to the pneumatic control nozzle assembly 10.

In the present application, the pneumatic control nozzle assembly 10 is provided to precisely control the flow or cutoff of the liquid, thereby effectively regulating the application of the liquid.

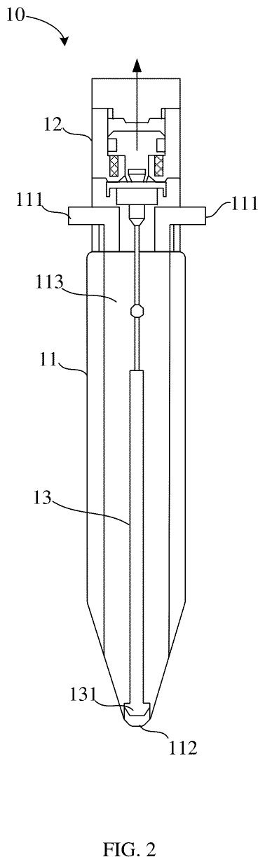

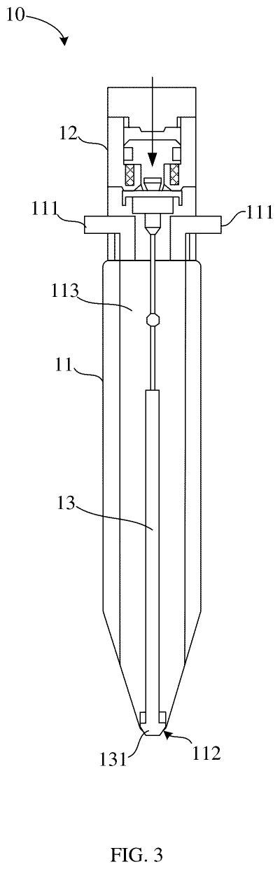

Please refer to FIG. 2 and FIG. 3, FIG. 2 is a schematic diagram showing a nozzle body of a pneumatic control nozzle assembly in an open state according to an embodiment of the present application, and FIG. 3 is a schematic diagram showing a nozzle body of a pneumatic control nozzle assembly in a closed state according to an embodiment of the present application. The pneumatic control nozzle assembly 10 includes a nozzle body 11, a pneumatic driving part 12, and a closed movable element 13. The pneumatic driving part 12 is connected to the nozzle body 11 and the closed movable element 13.

As shown in FIG. 2 and FIG. 3, the nozzle body 11 includes an inlet end 111, an outlet end 112, and an internal channel 113. The internal channel 113 connects the inlet end 111 and the outlet end 112. In the present application, the nozzle body 11 allows liquid from the liquid supply system 30 to enter through the inlet end 111, and the liquid is discharged from the outlet end 112 after flowing through the internal channel 113. It should be noted that, in the present application, the inlet end 111 of the nozzle body 11 refers to an end connected to the liquid supply system 30, and the outlet end 112 of the nozzle body 11 is an end of the nozzle body 11 and also refers to an end point of the internal channel 113.

As shown in FIG. 2 and FIG. 3, in this embodiment, the nozzle body 11 includes two inlet ends 111. Correspondingly, the liquid supply system 30 includes a liquid supply source and a pipeline assembly. The pipeline assembly is connected between the liquid supply source and the nozzle body 11. The liquid supply source is configured to provide two different process liquids, and the pipeline assembly is responsible for transmitting the two liquids to the two inlet ends 111 of the nozzle body 11 respectively. The nozzle body 11 receives different process liquids through the two inlet ends 111 and mixes them in the internal channel 113. This design allows different types or concentrations of liquids to be mixed inside the nozzle body 11 according to process requirements to achieve the best etching or cleaning effect. Furthermore, the design using a single nozzle body 11 prevents a problem of providing multiple nozzles which would occupy too much space, thereby providing a more compact and efficient solution. It should be understood that in different embodiments, more than two inlet end 111 designs may be configured to meet more complex process requirements, but the present invention is not limited thereto.

As shown in FIG. 2 and FIG. 3, the closed movable element 13 is movably disposed in the internal channel 113 of the nozzle body 11. In this embodiment, the closed movable element 13 is a straight long rod without any bends, one end of which is connected to the pneumatic driving part 12, and the other end of which extends toward the outlet end 112 of the nozzle body 11. This straight, unbendable long rod structure reduces manufacturing difficulty, improves process accuracy and component durability.

As shown in FIG. 2 and FIG. 3, according to a positive pressure gas or negative pressure gas provided by the gas supply device 40, the pneumatic driving part 12 drives the closed movable element 13 to perform a linear movement in the internal channel 113, so that the nozzle body 11 changes between an open state and a closed state. Specifically, the linear movement of the closed movable element 13 includes movement toward or away from the outlet end 112 of the nozzle body 11. This design allows the closed movable element 13 to move freely in the internal channel 113, thereby achieving precise adjustment of the flow or cutoff of the liquid. This not only simplifies the operation process, but also significantly improves the overall performance and long-term reliability of the system, ensuring the stability and efficiency of the pneumatic control nozzle assembly 10 in long-term use.

As shown in FIG. 2, the gas supply device 40 provides the negative pressure gas, so that the pneumatic driving part 12 drives the closed movable element 13 to move in a direction away from the outlet end 112 of the nozzle body 11, thereby placing the nozzle body 11 in the open state. When the nozzle body 11 is in the open state, an end 131 of the closed movable element 13 is spaced a distance from the outlet end 112 of the nozzle body 11 and a tube wall of the internal channel 113. In this case, the liquid in the internal channel 113 flows toward the outlet end 112 through gaps between the closed movable element 13 and the tube wall of the internal channel 113, and is finally discharged from the outlet end 112.

As shown in FIG. 3, the gas supply device 40 provides the positive pressure gas, so that the pneumatic driving part 12 drives the closed movable element 13 to move toward the outlet end 112 of the nozzle body 11 until the closed movable element 13 plugs the outlet end 112 of the nozzle body 11, thereby placing the nozzle body 11 in the closed state. It should be understood that an configuration of the end 131 of the closed movable element 13 matches configurations of the outlet end 112 of the nozzle body 11 and an end point of the internal channel 113 to ensure that the closed movable element 13 can completely plug the outlet end 112 of the nozzle body 11.

As shown in FIG. 3, in this embodiment, when the nozzle body 11 is in the closed state, the end 131 of the closed movable element 13 is flush with the outlet end 112 of the nozzle body, and the end 131 of the closed movable element 13 is exactly located at the end point of the inner channel 113 of the nozzle body 11. In this way, the end 131 of the closed movable element 13 does not leave any space or channel for accommodating residual liquid on a side facing outside, thereby ensuring that no additional liquid drips from the nozzle body 11 in the closed state.

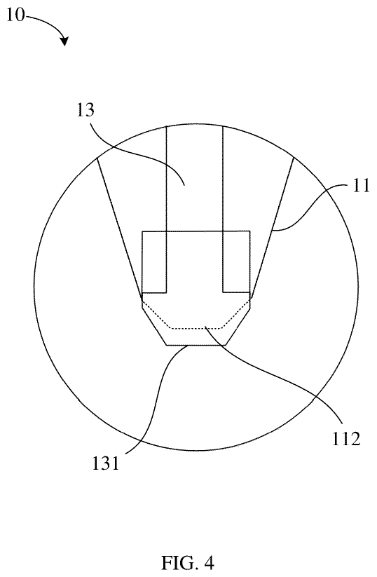

Please refer to FIG. 4, which is a partial enlarged view of a nozzle body of a pneumatic control nozzle assembly in a closed state according to another embodiment of the present application. In this embodiment, when the nozzle body 11 is in the closed state, the end 131 of the closed movable element 13 protrudes out of the outlet end 112 of the nozzle body 11. At this time, the end wall of the closed movable element 13 will tightly abut against the tube wall at the end of the internal channel 113, ensuring that there is no gap between the closed movable element 13 and the tube wall. Furthermore, since the closed movable element 13 protrudes out of the outlet end 112, no space or passage for accommodating the residual liquid is left on the side of the end 131 of the closed movable element 13 facing the outside. Therefore, this design can effectively prevent extra liquid from dripping from the nozzle body 11 in the closed state, thereby achieving a good sealing effect.

In some embodiments, the substrate processing device may further include a suck back mechanism. The suck back mechanism can be connected to the pneumatic control nozzle assembly 10 through the inlet end 111 of the nozzle body 11. In addition, the suck back mechanism can also be selectively connected to the pneumatic control nozzle assembly 10 through another additional opening, which is different from the inlet end 111 and the outlet end 112. A main function of the suck back mechanism is to draw the liquid away from the internal channel 113. Specifically, when the etching or cleaning process is stopped, the liquid output of the liquid supply system 30 is first turned off. Then, the suck back mechanism draws away the residual liquid in the internal channel 113. Finally, the closed movable element 13 is driven by the pneumatic driving part 12 to completely close the outlet end 112 of the nozzle body 11. By setting the suck back mechanism, it is ensured that the liquid inside the nozzle body 11 can be completely removed when the process is stopped, thereby effectively avoiding a risk of unexpected liquid dripping.

The present application also provides a control method of a substrate processing device, where the control method is executed by the above-mentioned substrate processing device 1, and the structure of the substrate processing device 1 is as described above and will not be elaborated herein. In addition, the substrate processing device 1 may further include a host, which is communicatively connected with each component of the substrate processing device 1. The host includes a processor and a memory that are electrically connected to each other. It should be understood that the host may also include one or more of the following components: a circuit board, a power supply circuit, etc. The processor and the memory are arranged on a circuit board. The memory is configured to store executable program codes. The processor reads the executable program codes stored in the memory and runs programs corresponding to the executable program codes to execute the control method of the present application.

In this embodiment, the processor is generally configured to control an overall operation of the host. The processor may include one or more processors to execute instructions and thereby perform actions in all or part of the steps in the operation of the substrate processing device 1 described above. Additionally, the processor may include one or more modules that facilitate interaction between the processor and other components. For example, the processor may include a communication module to facilitate interaction between communication components and the processor. The memory is configured to store various types of data to support host operations. Examples of such data include instructions for any application or method operating on the host. The memory may be implemented using any type of volatile or non-volatile storage device, or a combination thereof. A power circuit supplies power to various components of the host. The power circuitry may include a power management system, one or more power supplies, and any other components associated with the generation, management, and distribution of power to the host. In an exemplary embodiment, the host may be implemented by an independent terminal device or an electronic component such as a controller or a microcontroller integrated in the substrate processing device 1.

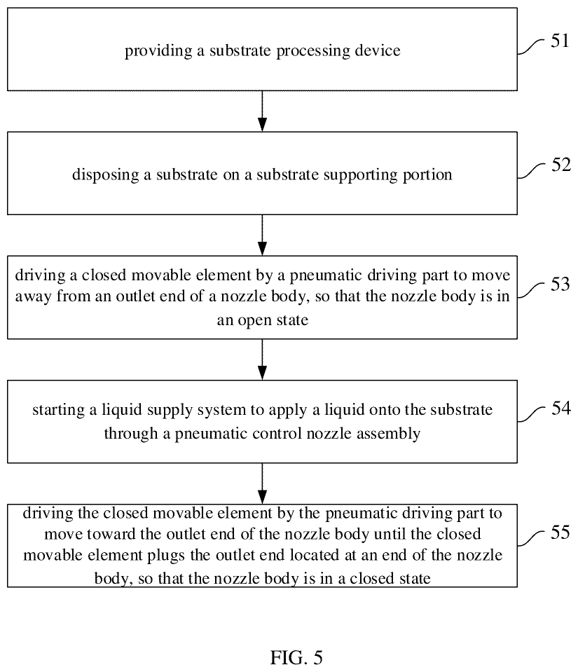

Please refer to FIG. 5, which is a flowchart of a control method of a substrate processing device according to an embodiment of the present application. The control method of the present application includes: first, in step 51, providing the substrate processing device 1 as described above.

As shown in FIG. 1 and FIG. 5, in step 52, a substrate 2 is disposed on the substrate supporting portion 20.

As shown in FIG. 1, FIG. 2, and FIG. 5, in step 53, the closed movable element 13 is driven by the pneumatic driving part 12 to move away from the outlet end 112 of the nozzle body 11 so that the nozzle body 11 is in the open state. Specifically, the gas supply device 40 provides negative pressure gas, so that the pneumatic driving part 12 drives the closed movable element 13 to move in a direction away from the outlet end 112 of the nozzle body 11, thereby placing the nozzle body 11 in the open state.

As shown in FIG. 1, FIG. 2, and FIG. 5, in step 54, the liquid supply system 30 is started to apply liquid to the substrate 2 through the pneumatic control nozzle assembly 10. It should be understood that when the nozzle body 11 is in the open state, the end 131 of the closed movable element 13 is spaced a distance from the outlet end 112 of the nozzle body 11 and the tube wall of the internal channel 113. In this case, the liquid in the internal channel 113 flows toward the outlet end 112 through the gaps between the closed movable element 13 and the tube wall of the internal channel 113, and is finally discharged from the outlet end 112.

As shown in FIG. 1, FIG. 3, and FIG. 5, in step 55, the closed movable element 13 is driven by the pneumatic driving part 12 to move toward the outlet end 112 of the nozzle body 11 until it plugs the outlet end 112 located at the end of the nozzle body 11, so that the nozzle body 11 is in the closed state. Specifically, the gas supply device 40 provides positive pressure gas, so that the pneumatic driving part 12 drives the closed movable element 13 to move toward the outlet end 112 of the nozzle body 11 until the closed movable element 13 plugs the outlet end 112 of the nozzle body 11, thereby placing the nozzle body 11 in the closed state. It should be understood that the configuration of the end 131 of the closed movable element 13 matches the configurations of the outlet end 112 of the nozzle body 11 and the end point of the internal channel 113 to ensure that the closed movable element 13 can completely plug the outlet end 112 of the nozzle body 11.

In some embodiments, the substrate processing device may further include the suck back mechanism. The suck back mechanism can be connected to the pneumatic control nozzle assembly 10 through the inlet end111 of the nozzle body11 or an additional opening. Furthermore, while driving the closed movable element 13 toward the outlet end 112 of the nozzle body 11 by the pneumatic driving part 12, the control method further includes: stopping the liquid supply system 30, and drawing a residual liquid away from the internal channel 113 by the suck back mechanism. Specifically, when the etching or cleaning process is stopped, the liquid output of the liquid supply system 30 is first turned off. Then, the suck back mechanism draws away the residual liquid in the internal channel 113. Finally, proceed to step 55 to drive the closed movable element 13 through the pneumatic driving part 12 to completely close the outlet end 112 of the nozzle body 11. In this embodiment, the suck back mechanism is provided to ensure that the liquid inside the nozzle body 11 can be completely removed when the process is stopped, thereby effectively avoiding a risk of unexpected liquid dripping.

Compared with the prior art, the present application provides the pneumatic control nozzle assembly, the substrate processing device and the control method thereof. When the nozzle body is in the closed state, the closed movable element plugs the outlet end at the end of the nozzle body, so that no space or channel for accommodating residual liquid is left on a side of the closed movable member facing outward. This ensures that no excess liquid drips from the nozzle body in the closed state.

The above are only preferred embodiments of the present application. It should be noted that, for those skilled in the art, without departing from the principles of the present application, several improvements and modifications may be made, and these improvements and modifications should also be considered as the protection scope of this application.

What is claimed is:

1. A pneumatic control nozzle assembly, comprising:
a nozzle body comprising an inlet end, an outlet end, and an internal channel, wherein the internal channel connects the inlet end and the outlet end;
a closed movable element movably disposed in the internal channel of the nozzle body; and
a pneumatic driving part connected to the nozzle body and the closed movable element, and configured to drive the closed movable element to perform a linear movement in the internal channel so that the nozzle body changes between an open state and a closed state, wherein when the nozzle body is in the closed state, the closed movable element plugs the outlet end located at an end of the nozzle body.

2. The pneumatic control nozzle assembly of claim 1, wherein when the nozzle body is in the closed state, an end of the closed movable element protrudes out of the outlet end of the nozzle body.

3. The pneumatic control nozzle assembly of claim 1, wherein when the nozzle body is in the closed state, an end of the closed movable element is flush with the outlet end of the nozzle body.

4. The pneumatic control nozzle assembly of claim 1, wherein when the nozzle body is in the open state, an end of the closed movable element is spaced a distance from the outlet end of the nozzle body and a tube wall of the internal channel.

5. The pneumatic control nozzle assembly of claim 1, wherein the linear movement of the closed movable element comprises movement toward or away from the outlet end of the nozzle body.

6. A substrate processing device, comprising:
a substrate supporting portion configured to support a substrate;
a liquid supply system configured to provide a liquid; and
a pneumatic control nozzle assembly connected to the liquid supply system and configured to apply the liquid to the substrate, wherein the pneumatic control nozzle assembly comprises:
a nozzle body comprising an inlet end, an outlet end, and an internal channel, wherein the internal channel connects the inlet end and the outlet end, and the nozzle body allows the liquid to enter through the inlet end and flow through the internal channel and then be discharged from the outlet end;
a closed movable element movably disposed in the internal channel of the nozzle body; and
a pneumatic driving part connected to the nozzle body and the closed movable element, and configured to drive the closed movable element to perform a linear movement in the internal channel so that the nozzle body changes between an open state and a closed state, wherein when the nozzle body is in the closed state, the closed movable element plugs the outlet end located at an end of the nozzle body.

7. The substrate processing device of claim 6, wherein when the nozzle body is in the closed state, an end of the closed movable element protrudes out of the outlet end of the nozzle body.

8. The substrate processing device of claim 6, wherein when the nozzle body is in the closed state, an end of the closed movable element is flush with the outlet end of the nozzle body.

9. A control method of a substrate processing device, comprising:
providing a substrate processing device, wherein the substrate processing device comprises a substrate supporting portion, a liquid supply system, and a pneumatic control nozzle assembly connected to the liquid supply system; and the pneumatic control nozzle assembly comprises a nozzle body, a closed movable element, and a pneumatic driving part, the nozzle body comprises an inlet end, an outlet end, and an internal channel, the closed movable element is movably disposed in the internal channel of the nozzle body, and the pneumatic driving part is connected to the nozzle body and the closed movable element;
disposing a substrate on the substrate supporting portion;
driving the closed movable element by the pneumatic driving part to move away from the outlet end of the nozzle body, so that the nozzle body is in an open state;
starting the liquid supply system to apply a liquid onto the substrate through the pneumatic control nozzle assembly; and
driving the closed movable element by the pneumatic driving part to move toward the outlet end of the nozzle body until the closed movable element plugs the outlet end located at an end of the nozzle body, so that the nozzle body is in a closed state.

10. The control method of the substrate processing device of claim 9, wherein before driving the closed movable element by the pneumatic driving part to move toward the outlet end of the nozzle body, the control method further comprises:
stopping the liquid supply system; and
drawing a residual liquid away from the internal channel by a suck back mechanism.
